(19) United States
(12) Patent Application Publication
(10) Pub. No.: US 2008/0310566 A1
(43) Pub. Date: Dec. 18, 2008

(54) FREQUENCY SYNCHRONIZING CIRCUIT, METHOD, AND RECEIVING APPARATUS USING THE CIRCUIT AND THE METHOD

(75) Inventors: Makoto Tsuruta, Kawasaki-shi (JP); Jun Mitsugi, Yokohama-shi (JP); Hidehiro Matsuoka, Yokohama-shi (JP); Mikihiro Yamazaki, Kawasaki-shi (JP); Shizuo Akiyama, Yokohama-shi (JP)

Correspondence Address: AMIN, TUROCY & CALVIN, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/054,609

(22) Filed: Mar. 25, 2008

(30) Foreign Application Priority Data
Jun. 18, 2007 (JP) 2007-160423

(51) Int. Cl. H04B 1/10; H03L 7/00

(52) U.S. Cl. 375/350; 327/141

(57) ABSTRACT

A frequency synchronizing circuit includes a first raising unit configured to raise a received signal by a first power to obtain a first raised signal, a filter to suppress noise in the first raised signal to obtain a filtered signal, a second raising unit configured to raise the filtered signal by a second power to obtain a second raised signal, an estimating unit configured to estimate a frequency offset in the received signal based on the second raised signal to obtain an estimated value, and an offset-cancelling unit configured to cancel the estimated value from the received signal, to output an offset cancelled signal.

### CROSS-REFERENCE TO RELATED APPLICATIONS

This application is based upon and claims the benefit of priority from prior Japanese Patent Application No. 2007-160423, filed Jun. 18, 2007, the entire contents of which are incorporated herein by reference.

### BACKGROUND OF THE INVENTION

1. Field of the Invention

The present invention relates to a frequency synchronizing circuit and method which cancel frequency offsets, and a receiving apparatus using the circuit and the method.

2. Description of the Related Art

In radio communication, the frequency must be the same in the transmitting side and the receiving side in most cases. 802.11 High-Speed Radio LAN Textbook, ISBN 4-87280-490 (hereinafter referred to as Related Art) discloses a frequency synchronizing method for use in radio communications systems that use orthogonal frequency division multiplexing (OFDM) signals.

In the Related Art, the frequency synchronization is performed in two steps. The first step is rough frequency synchronization in which the phase rotation is estimated and corrected by utilizing the guard interval correlation to which a cyclic prefix is applied. The second step is fine frequency synchronization in which the phase rotation is estimated and corrected at each sub-carrier after fast Fourier transform (FFT). In any radio communications system in which a cyclic prefix is applied to the guard intervals, the end portion of each OFDM symbol is copied as guard intervals onto the head portion of the symbol, and the phase rotation can be estimated from the correlation of the repeated guard intervals.

JP-A 9-214293 (KOKAI) discloses, in paragraphs [0002] to [0004] and in FIG. 43, a method of estimating a frequency offset required in frequency synchronization, after the received signal has been raised by i-th (i is a certain number) power and the modulated component has thereby been removed from the signal.

The method described in the Related Art is designed for use in radio communications systems in which a cyclic prefix is applied to the guard intervals. Hence, the frequency offset cannot be effectively cancelled in radio communications systems if a unique word is applied to the guard intervals or in the case where the signals to be transmitted are so-called burst signals that have a short duration.

By contrast, in the method described in JP-A 9-214293 (KOKAI), if the power is too large, the signal-to-noise ratio (SNR) will decrease, lowering the accuracy of estimating the frequency offset. Consequently, the upper limit of the power is small, which inevitably limits the frequency offset that can be cancelled.

### BRIEF SUMMARY OF THE INVENTION

According to an aspect of the invention, there is provided a frequency synchronizing circuit comprising: a first raising unit configured to raise a received signal by a first power to obtain a first raised signal; a filter to suppress noise in the first raised signal to obtain a filtered signal; a second raising unit configured to raise the filtered signal by a second power to obtain a second raised signal; an estimating unit configured to estimate a frequency offset in the received signal based on the second raised signal to obtain an estimated value; and an offset-cancelling unit configured to cancel the estimated value from the received signal, to output an offset cancelled signal.

According to another aspect of the invention, there is provided a frequency synchronizing circuit comprising: an offset-cancelling unit configured to cancel an cumulated estimation value of a frequency offset from an input signal, to output an offset cancelled signal; a first raising unit configured to raise the offset cancelled signal by a first power to obtain a first raised signal; a filter which suppresses noise in the first raised signal to obtain a filtered signal; a second raising unit configured to raise the filtered signal by a second power to obtain a second raised signal; an estimating unit configured to estimate the frequency offset based on the second raised signal, to obtain the cumulated estimation value and an estimated value of residual frequency offset; and a setting unit configured to set the first power to such a value that the estimated value of residual frequency offset may fall within a specific tolerance range.

### BRIEF DESCRIPTION OF THE SEVERAL VIEWS OF THE DRAWING

FIG. 1 is a block diagram showing a frequency synchronizing circuit according to a first embodiment;

FIG. 2 is a block diagram showing the raising unit shown in FIG. 1;

FIG. 3A is a graph representing a power spectrum of raised signals obtained by raising the received signal at one time;

FIG. 3B is a graph representing a power spectrum of raised signals obtained by raising the received signal in two steps;

FIG. 4 is a conceptual representation of a frequency offset estimated by the frequency-offset estimating unit shown in FIG. 1;

FIG. 5A is a graph showing a frequency-offset error estimated of an 8th raised signal;

FIG. 5B is a graph showing a offset error estimated of a 16th raised signal;

FIG. 5C is a graph showing a offset error estimated of a 32nd raised signal;

FIG. 6 is a flowchart explaining the operation of the frequency synchronizing circuit shown in FIG. 1;

FIG. 7 is a block diagram showing a frequency synchronizing circuit according to a second embodiment;

FIG. 8 is a block diagram showing a frequency synchronizing circuit according to a third embodiment;

FIG. 9 is a block diagram showing a frequency synchronizing circuit according to a fourth embodiment;

FIG. 10 is a block diagram showing a filter used in a frequency synchronizing circuit according to a fifth embodiment; and

FIG. 11 is a block diagram showing a receiving apparatus according to a sixth embodiment.

### DETAILED DESCRIPTION OF THE INVENTION

Embodiments of the present invention will be described with reference to the accompanying drawings.

### First Embodiment

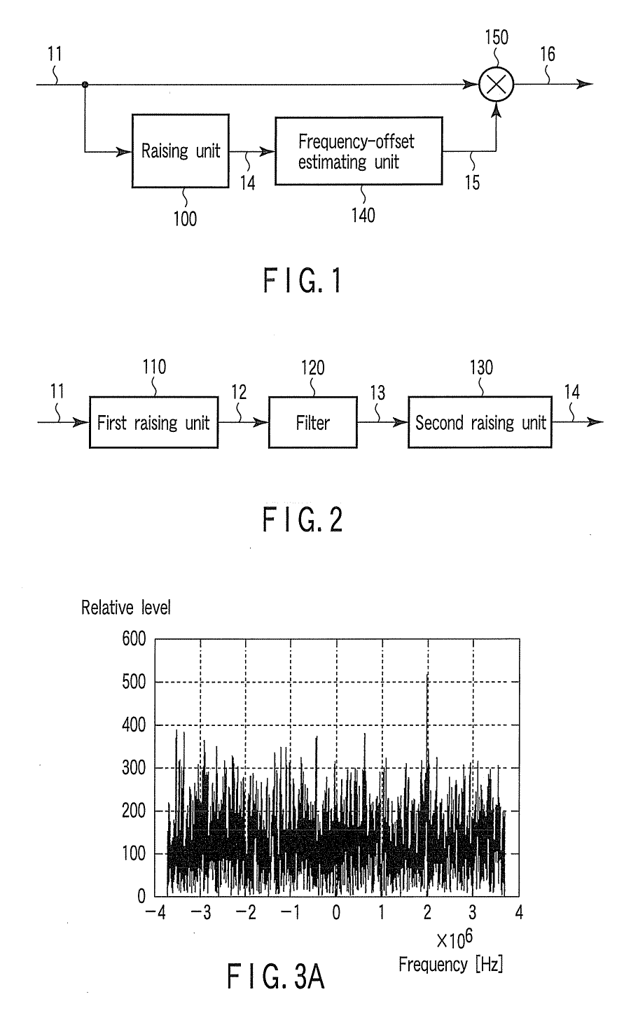

As FIG. 1 shows, a frequency synchronizing circuit according to a first embodiment of this invention has a raising unit 100, a frequency-offset estimating unit 140, and an offset-cancelling unit 150. A received signal 11 input to this frequency synchronizing circuit, which contains digitally modulated symbols, is supplied to the raising unit 100 and the offset-cancelling unit 150.

The raising unit 100 raises a frequency of the received signal 11 by a preset power. The received signal 11 thus raised is input to the frequency-offset estimating unit 140.

The frequency-offset estimating unit 140 estimates the frequency offset of the received signal 11 from the signal raised by the raising unit 100. Since the received signal 11 has been raised by the raising unit 100, the accuracy of estimating the frequency offset can be raised as will be described later. The estimated frequency offset 15 is input to the offset-cancelling unit 150.

The offset-cancelling unit 150 includes, for example, a mixer and a filter. In the mixer, the received signal 11 is multiplied by a signal corresponding to the estimated frequency offset 15 (i.e., estimated offset frequency). The mixer obtains two frequency components, i.e., one being the sum of the frequency of the received signal 11 and the estimated frequency offset 15, and the other being the difference between the frequency of the received signal 11 and the estimated frequency offset 15. In the offset-cancelling unit 150, the filter removes the sum frequency-component from the output of the mixer. As a result, the offset-cancelling unit 150 outputs only the difference frequency-component.

The raising unit 100 will be described. As shown in FIG. 2, the raising unit 100 has a first raising unit 110, a filter 120, and a second raising unit 130. The raising unit 100 raises an input signal in two steps.

The first raising unit 110 raises an input signal by a first power. The signal thus raised is supplied to the filter 120. Preferably, the first power should have such a value that a modulated component, if any, may be cancelled from the received signal 11. Assume that the received signal 11 is composed of a row of symbols modulated by means of quadrature phase shift keying (QPSK). Then, the signal points of symbols are arranged in the I-Q plane, defining a constellation. In the constellation, symbol “00” is located at the π/4-point in the I-Q plane, symbol “01” at the 3π/4-point in the I-Q plane, symbol “11” at the 5π/4-point in the I-Q plane, and symbol “10” at the 7π/4-point in the I-Q plane.

If the first power is set to “4,” the modulated component of every symbol will be removed from the received signal 11. That is, if the received signal 11 is raised by a power of 4, the modulated component of symbol “00” will have phase π, the modulated component of symbol “01” will have phase 3π (=π), the modulated component of symbol “11” will have phase 5π (=π), and the modulated component of symbol “10” will have phase 7π (=π). A first raised signal 12 that has no modulated components of symbols is thereby obtained.

The filter 120 extracts the frequency offset raised by the first power from the first raised signal 12 output from the first raising unit 110. That is, the filter 120 allows the passage of the signal component of a first band close to the frequency offset raised by the first power, suppresses the noise component of a second band other than the first band, and supplies a filtered signal 13, i.e., signal component of the first band, to the second raising unit 130. The filter 120 is not limited in configuration. Nonetheless, it is configured to perform convolution, thus accomplishing a filtering process.

The second raising unit 130 raises the filtered signal 13 output from the filter 120 by a second power, outputting a second raised signal 14. The second power will be explained, with reference to the following table.

TABLE 1

| Modulation | Ultimate | First | Second |
|---|---|---|---|
| scheme | power | power | power |
| BPSK | P | 2 | P-2 |
| π/2BPSK | P | 4 | P-4 |
| QPSK | P | 4 | P-4 |
| π/4QPSK | P | 8 | P-8 |
| M-PSK | P | M | P-M |
| M-QAM | P | 4 | P-4 |

As seen from Table 1, the second power is a value obtained by subtracting the first power from the ultimate power P of the raising unit 100. The ultimate power P is the factor that must be applied in order to suppress the estimated offset error, which will be described later, within a specific tolerance inherent to the system that uses the frequency synchronizing circuit according to this embodiment. The relation between the modulation scheme and the first power is not limited to the relation shown in Table 1, which is nothing more than an example. That is, the first power shown in Table 1 may be increased or decreased, and the second power may be changed in inverse proportion to the first power.

The technical significance of raising the input signal in two steps in the frequency synchronizing circuit according to this embodiment will be described.

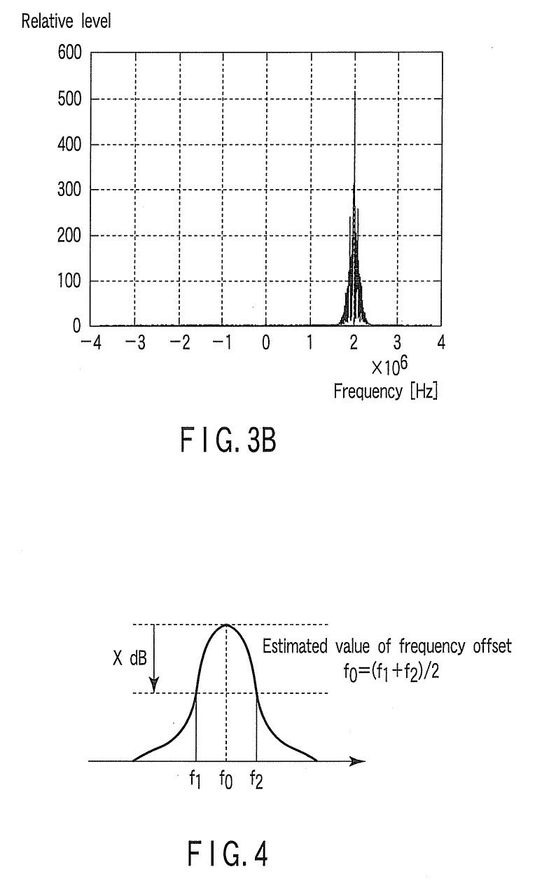

Assume that the raising unit 100 shown in FIG. 1 is replaced by a raising unit that raises the input signal composed a row of QPSK-modulated symbols, only once by the power P. Then, the raising unit 100 generates a raised signal shown in FIG. 3A. Generally, the signal-to-noise ratio (SNR) decreases by 10 log₁₀m (dB) when the signal is raised by m. The noise component will adversely influence the signal component over a broad band. Hence, it is difficult for the frequency-offset estimating unit 140 to estimate the frequency offset of the signal raised at one time by the raising unit.

Assume that the input is raised in two steps as shown in FIG. 2, and that the first raising unit 110 raises the received signal 11 by the first power “4,” the filter 120 performs the filtering on the first raised signal 12 thus obtained, and the second raising unit 130 raises the same by the second power “P-4.” Then, the second raised signal 14, which has a high SNR as shown in FIG. 3B, is generated.

That is, the first raising unit 110 uses only such first power that the filter 120 may suppress the noise and may extract the frequency offset. Since the filter 120 suppresses the noise existing at the second band of the first raised signal 12, thus excluding the first band near the frequency offset of the first raised signal 12, a decrease in the SNR can be minimized. Therefore, the second raised signal 14 generated by the second raising unit 130 has a high SNR as seen from FIG. 3B, and can facilitate the estimating of the frequency offset more reliably than the signal shown in FIG. 3A.

The frequency-offset estimating unit 140 estimates the frequency offset of the received signal 11 from the signal (i.e., the second raised signal 14) raised by the raising unit 100. The estimated frequency offset 15 thus estimated is input to the offset-cancelling unit 150. More precisely, the frequency-offset estimating unit 140 estimates the frequency offset from the second raised signal 14, using, for example, a discriminator (frequency discriminator) or FFT.

First, the technique of estimating the frequency offset by using the discriminator will be described. If the complex discrete time signal, x(n)=I(n)+jQ(n), which corresponds to a given sample number n, is input to the discriminator, the output of the discriminator f(n) will be expressed as follows:

$$f ( n ) = \frac{{f}_{s}}{2 π} Arc sin ( I ( n ) Q ( n + 1 ) - I ( n + 1 ) Q ( n ) ) \qquad ( 1 )$$

where fs is the sampling frequency.

The output f(n) of the discriminator is equivalent to the frequency offset. That is, the frequency offset can be estimated by detecting f(n) in the equation, by means of the discriminator.

The technique of estimating the frequency offset by using FFT will be described. If the complex discrete time signal x(n) (described above) is subjected to FFT, a power spectrum will be obtained. The frequency corresponding to the peak of this power spectrum is equivalent to the frequency offset. That is, the frequency offset can be estimated by detecting the frequency that imparts a peak to the power spectrum acquired by performing FFT.

Here, some techniques of estimating the frequency offset more accurately than those described above will be described.

First, the technique of estimating the frequency offset by using the output of the discriminator will be described. The frequency offset is estimated from the average of the outputs f(k) of the discriminator. The frequency offset fo is given as follows:

$${f}_{O} = \frac{1}{K} {\sum }_{k = 0}^{K - 1} f ( k ) \qquad ( 2 )$$

where K is the size of FFT. Note that the median of the outputs f(k) of the frequency offset may be applied, in place of the frequency offset fo.

The technique of estimating the frequency offset by means of FFT will be described. As the power spectrum shown in FIG. 4 indicates, the power sharply increases to the peak, by X dB, starting at frequency f1, and then sharply decreases from the peak, by X dB, ending at frequency f2. In this case, the frequency offset fo can be estimated from the arithmetic means of frequencies f1 and f2. Alternatively, the frequency offset fo can be estimated from the weighted means of the power spectrums p(k), using the following equation:

$${f}_{O} = \frac{{\sum }_{k = - K / 2}^{K / 2 - 1} k \cdot p ( k )}{{\sum }_{k = - K / 2}^{K / 2 - 1} \vert p ( k ) \vert} \qquad ( 3 )$$

where K is the size of FFT.

A further technique of estimating the frequency offset from the intervals between zero-cross-points will be described. Then, the frequency offset fo can be estimated by applying the following equation:

$${f}_{O} = \frac{1}{L} {\sum }_{i = 0}^{L - 1} \frac{1}{{T}_{d}^{i}} \qquad ( 4 )$$

where Tdi is the interval between the ith zero-cross-point and the (i+1)th zero-cross point, and L is the number of the zero-cross-points.

The frequency-offset estimating unit 140 can indeed estimate the frequency offset, as has been explained. However, in the technique of estimating the frequency offset by the discriminator, the SNR greatly influences the accuracy of frequency offset estimateence if the frequency is relatively low. In the technique of estimating the frequency offset using FFT, too, the accuracy is limited due to the frequency resolution per BIN, i.e., Δf. Nevertheless, the frequency-offset estimating unit 140 according to this embodiment estimates the frequency offset, not directly from the input signal, but indirectly from the raised signal. Hence, the accuracy of estimating can be raised, as will be explained below.

Consider the case where the frequency offset is estimated from the peak of the power spectrum obtained by performing FFT. The frequency offset fo of the input signal can be estimated as k*Δf, where k is the BIN number corresponding to the peak of the power spectrum, and Δf is the frequency resolution per BIN. In fact, however, the frequency offset fo may fall within the range of: (k−1)*Δf<fo<(k+1)*Δf. In other words, an error may arise in the estimated frequency offset, which is Δf at maximum. On the other hand, the frequency offset fmo (=m*fo) of the raised signal, which is the input signal raised by a power “m,” is estimated to be k*m*Δf. Hence, the frequency offset fmo may practically fall within the range of: (k*m−1)*Δf<fmo<(k*m+1)*Δf. If the frequency offset fmo is frequency-divided by “m”, the frequency offset fo will be estimated from the input signal. In this case, the frequency offset fo practically falls within the range of (k−1/m)*Δf<fo<(k+1/m)*Δf. Hence, the frequency-offset error, if any, is Δf/m at most. In the other words, the frequency-offset error can be reduced to 1/m, where m is the power. It should be noted that when the signal is raised by m as described above, the SNR decreases by 10 log₁₀m (dB). Hence, the signal-to-noise ratio (SNR) is finally 10 log₁₀(K/m), where K is the size of the FFT. Thus, if the power m is excessively large, the SNR will be degraded.

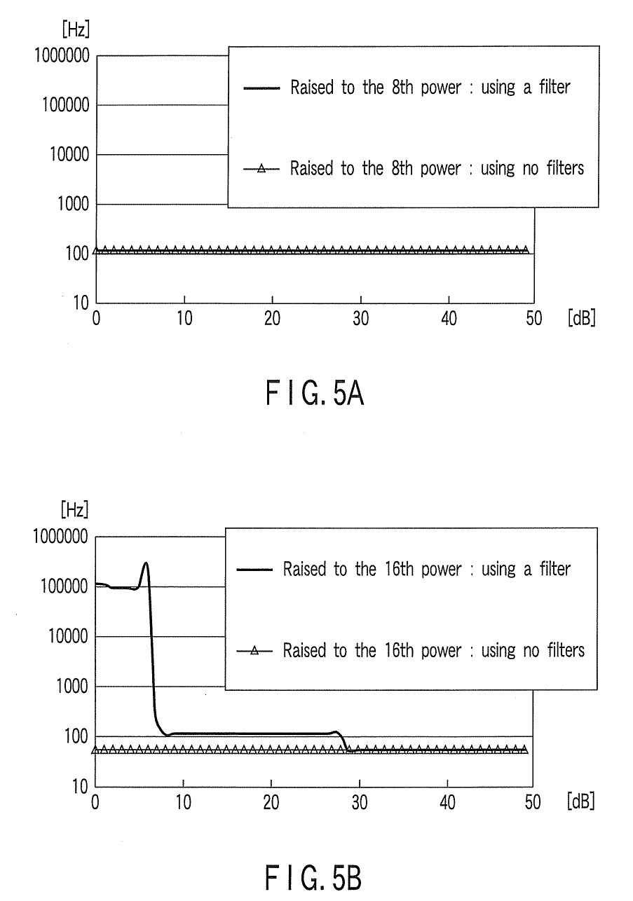

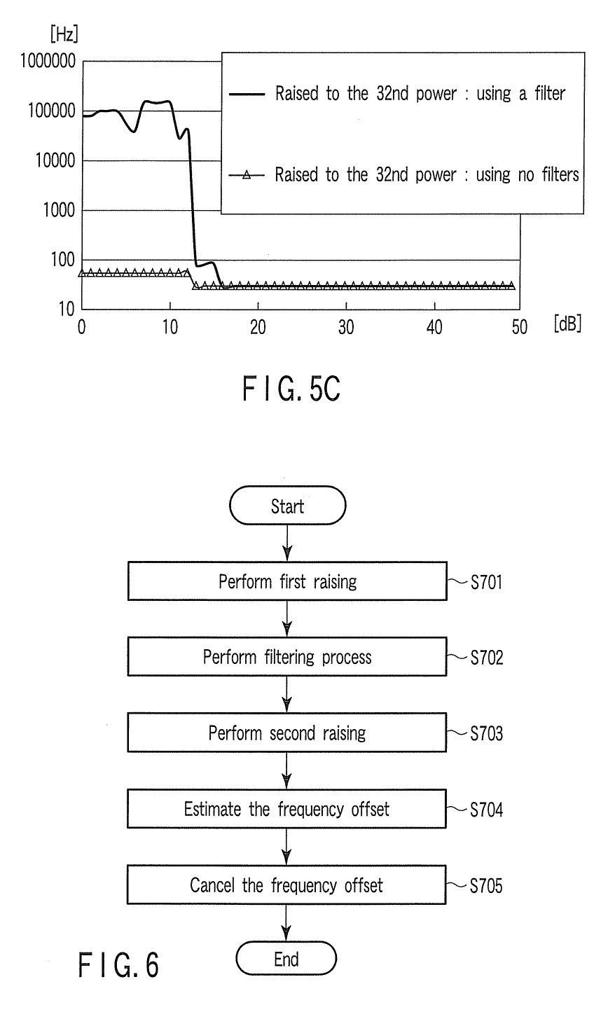

FIGS. 5A to 5C are graphs showing three offset errors, respectively, which are estimated when three signals raised by 8, 16, and 32, respectively, are input to the frequency-offset estimating unit 140. In FIGS. 5A to 5C, the SNR (dB) is plotted on the horizontal axis, and frequency offset error (Hz) is plotted on the vertical axis, each for one case where the filter 120 is used and for the other case where the filter 120 is not used. As can be seen from FIGS. 5A, 5B and 5C, the filter 120 reduces frequency-offset errors, particularly the error estimated from any raised signal that has a small SNR. Further, as evident from FIGS. 5A, 5B and 5C, the frequency-offset error decreases as the power increases.

The offset-cancelling unit 150 first cancels the estimated frequency offset 15 estimated by the frequency-offset estimating unit 140, and then outputs an offset cancelled signal 16.

The frequency synchronization according to this embodiment will be described, with reference to the flowchart in FIG. 6.

First, the input signal is raised by the first power (Step 701). Note that the first power has a value that can suppress the modulated component of the symbol contained in the input signal. Then, a filtering process is performed, suppressing the noise existing at the second band of the first raised signal 12 obtained in Step 701, not at the first band near the frequency offset (Step 702).

Next, the filtered signal 13 obtained in Step 702 is raised by the second power (Step 703). Note that the second power has a value that has been acquired by subtracting the first power from the power (ultimate power) that should be applied to suppress the estimated offset error within the specific tolerance inherent to the system that uses the frequency synchronization according to this embodiment.

Thereafter, a frequency offset is estimated from the second raised signal 14 obtained in Step 703 (Step 704). More precisely, the frequency offset is estimated by frequency-dividing, for example, the frequency corresponding to the peak of the power spectrum acquired by performing FFT on the second raised signal 14, by the ultimate power.

Further, the frequency offset acquired in Step S705 is cancelled from the above-mentioned input signal (Step S706). More precisely, the input signal is multiplied by the signal corresponding to frequency offset and extracted only the low-frequency component. The frequency offset is thereby cancelled from the input signal.

As described above, the input is raised in two steps in the present embodiment and a filtering process is performed between the steps of raising the input in the present embodiment. The present embodiment can therefore effectively cancel frequency offsets also in a system that uses burst signals that last for a relatively short time or unique words of Chinese terrestrial digital TV standard (DTMB) or 3GPP standard.

### Second Embodiment

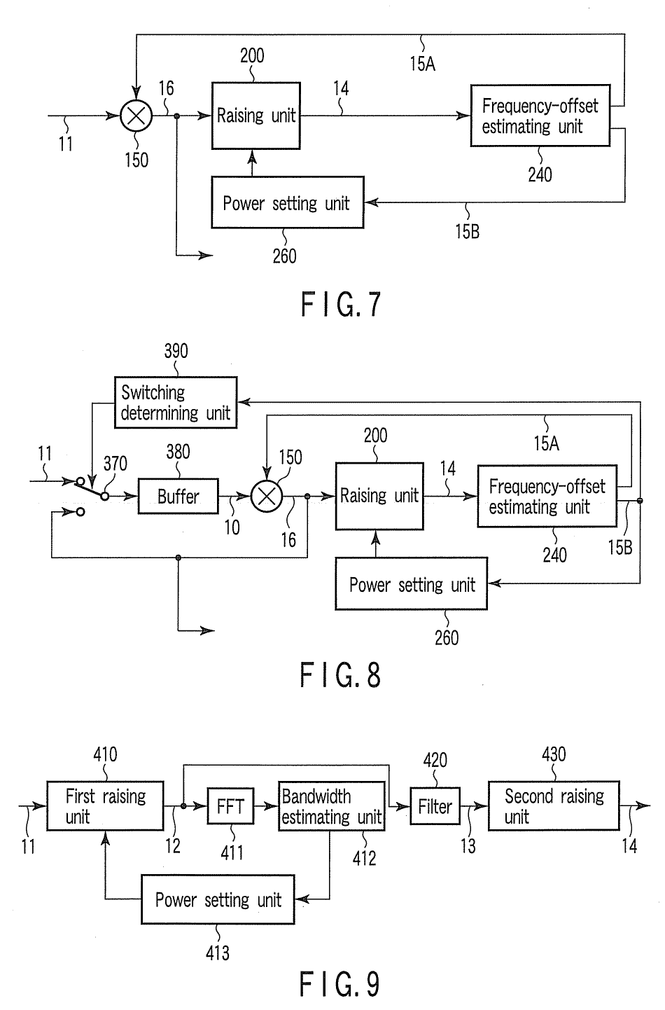

As FIG. 7 shows, a frequency synchronizing circuit according to a second embodiment of this invention has a raising unit 200, a frequency-offset estimating unit 240, an offset-cancelling unit 150, and a power setting unit 260. The components identical to those shown in FIG. 1 are designated by the same reference numerals In FIG. 7, and will not be described in detail.

The offset-cancelling unit 150 outputs an offset cancelled signal 16 that has been obtained by cancelling the cumulated estimation value 15B (accumulated estimated frequency offset), supplied from the frequency-offset estimating unit 240, from the received signal 11 that has digitally modulated symbols. The offset cancelled signal 16 is input to the raising unit 200.

The raising unit 200 is essentially the same as the raising unit 100 according to the first embodiment. Nonetheless, the raising unit 200 can change the second power in accordance with an ultimate power, if any factor was set by the power setting unit 260, as will be described later. The raising unit 200 performs the same process on the offset cancelled signal 16, as the raising unit 100 does in the first embodiment, generating a raised signal. The raised signal is input to the frequency-offset estimating unit 240.

The frequency-offset estimating unit 240 estimates a residual frequency offset from the raised signal, outputs the estimated residual frequency offset 15A to the power setting unit 260, and outputs the cumulated estimation value 15B of the residual frequency offsets to the offset-cancelling unit 150. As described above, the initial value of the cumulated estimation value 15B, which should be input to the offset-cancelling unit 150, is required to operate, for the first time, the frequency synchronizing circuit according to the present embodiment. The initial value is set to 0, for example. The frequency-offset estimating unit 240 estimates the frequency offset remaining in the offset cancelled signal 16, which has been output from the offset-cancelling unit 150, which is therefore free of the cumulated estimation value 15B and which has then been raised by the raising unit 200. Assume that the frequency-offset estimating unit 240 estimates the frequency offset by means of FFT. Then, the frequency-offset estimating unit 240 estimates the residual frequency offset by dividing the product of the BIN number and the frequency resolution Δf, by the power applied in the raising unit 200. Note that the BIN number corresponds to the peak of the power spectrum obtained from the amplitude spectrum of the raised signal. Assume that the ith estimated residual frequency offset is expressed as foi, the pth estimated residual frequency offset is expressed as fop and the cumulated estimation value 15B cancelled by the offset-cancelling unit 150 is given as: fo1+fo2+, . . . , +fop. Since the absolute value of the estimated residual frequency offset foi monotonically decreases with time, it approaches 0 every time the residual frequency is estimated. Hence, the cumulated estimation value 15B of the frequency offsets cancelled by the offset-cancelling unit 150 gradually converges to the real value.

The power setting unit 260 sets in the raising unit 200 the power determined from the estimated residual frequency offset 15A, which has been output from the frequency-offset estimating unit 240. From the sampling theorem, the largest power n that can be set in the raising unit 200 can be expressed as: n=fs/|2fo|, where fs is the sampling frequency and fo is the residual frequency offset. As pointed out above, the absolute value of the estimated residual frequency offset 15A output from the frequency-offset estimating unit 240 decreases with time and converges to 0. Therefore, the power that can be set in the power setting unit 260 becomes infinitely larger. The power setting unit 260 can therefore increase this factor infinitely. Hence, an optimal power can be set for any system that uses the frequency synchronizing circuit according to this embodiment.

In the present embodiment, as described above, the estimated residual values of frequency offsets are cumulated and the remaining frequency offset is estimated from the received signal, from which the cumulated estimated residual frequency offsets have been cancelled. Thus, the estimated value of the estimated residual frequency offset gradually converges to 0. Therefore, a desired power can be set, regardless of the sampling frequency, and the frequency offset can be effectively cancelled.

### Third Embodiment

As FIG. 8 shows, a frequency synchronizing circuit according to a third embodiment of the present invention has a switch 370, a buffer 380, an offset-cancelling unit 150, a raising unit 200, a frequency-offset estimating unit 240, a power setting unit 260, and a switching determining unit 390. The components identical to those shown in FIG. 7 are designated by the same reference numerals in FIG. 8, and will not be described in detail.

The switch 370 switches connection, supplying to the buffer 380, either a received signal 11 containing a digitally modulated symbols or an offset cancelled signal 16 output from the offset-cancelling unit 150, which has been designated by the switching determining unit 390.

The buffer 380 temporarily stores the signal input via the switch 370 and outputs the same to the offset-cancelling unit 150. The signal stored in the buffer 380 is updated by any signal input.

The offset-cancelling unit 150 cancels the cumulated estimation value 15B of the frequency offsets, which has been supplied from the frequency-offset estimating unit 240. The offset-cancelling unit 150 therefore generates an offset cancelled signal 16, which is supplied to the raising unit 200. The offset cancelled signal 16 may be input to the buffer 380 via the switch 370 as described above, depending on the connection state of the switch 370.

The frequency-offset estimating unit 240 estimates a residual frequency offset from the raised signal input from the raising unit 200 as in the second embodiment described above, thus generating the estimated residual frequency offset 15A and a cumulated estimation value 15B of the frequency offsets. The estimated residual frequency offset 15A is supplied to the power setting unit 260 and switching determining unit 390. The cumulated estimation value 15B is supplied to the offset-cancelling unit 150.

The switching determining unit 390 compares, for example, the absolute value of the estimated residual frequency offset 15A, supplied from the power setting unit 260, with a preset threshold value. The switching determining unit 390 then operates the switch 370 in accordance with the result of this comparison. To be more specific, if the absolute value is smaller than the threshold value, the switching determining unit 390 operates the switch 370, inputting the received signal 11 to the buffer 380. Conversely, if the absolute value is not smaller than the threshold value, the switching determining unit 390 operates the switch 370, inputting the offset cancelled signal 16 from the offset-cancelling unit 150 to the buffer 380. Note that the condition based on which the switching determining unit 390 determines the switching is not limited to the above-specified one. For example, the switching determining unit 390 may operate the switch 370 based on whether or not the cumulated estimation value 15B of the frequency offsets falls outside a predetermined range. Alternatively, the switching determining unit 390 may operate the switch 370 based on whether or not the bit-error rate (BER) falls below a predetermined value, even in any receiver that uses the frequency synchronizing circuit according to the present embodiment.

As described above, in the present embodiment, synchronization is repeated until the frequency offset is fully cancelled. A frequency offset can therefore be effectively cancelled from even a signal having a limited duration, such as a burst signal. Moreover, this embodiment is useful in any system that needs to receive signals at high speed.

### Fourth Embodiment

A frequency synchronizing circuit according to a fourth embodiment of the invention is different from any one of the first to third embodiments described above, only in that the raising unit is replaced by a raising unit of the type shown in FIG. 9. As FIG. 9 shows, the raising unit has a first raising unit 410, a fast-Fourier transformer (FFT) 411, a band-width estimating unit 412, a power setting unit 413, a filter 420, and a second raising unit 430.

The first raising unit 410 is essentially the same as the first raising unit 110 incorporated in the first embodiment. Nonetheless, the first power is set in the first raising unit 410 by the power setting unit 413 as will be described later. That is, the first raising unit 410 raises the received signal 11 containing a digitally modulated symbol, by the first power set by the power setting unit 413, thereby generating a first raised signal 12. The first raised signal 12 is supplied to the filter 420. The first raised signal 12 is output to the FFT 411, too.

The FFT 411 also performs FFT on the first raised signal 12, generating a power spectrum. The power spectrum thus generated is supplied to the band-width estimating unit 412.

The band-width estimating unit 412 estimates the bandwidth of the first raised signal 12, from the above-mentioned power spectrum. The method of estimating the bandwidth is not limited to a particular one. Nevertheless, the band-width estimating unit 412 may perform the following method to calculate the bandwidth of the first raised signal 12. First, the band-width estimating unit 412 detects the maximum peak of the power spectrum. Then, the band-width estimating unit 412 detects two points where the signal level is lower by XdB than the maximum peak and frequency is lower and higher than that at the maximum peak, respectively. The distance between the two points is regarded as an estimated bandwidth. The level decrease XdB from the maximum peak is a value experimentally acquired and is not limited to a specific one. The band-width estimating unit 412 further detects a line spectrum for the plurality of peaks existing in the power spectrum. The line spectrum is a spectrum in which a great level attenuation is observed, ranging from one BIN to several BINs. If no line spectrum is detected, the first raising unit 410 is considered to have raised the received signal 11 insufficiently. In this case, it can be determined that the modulated component has not been fully removed from the received signal 11. The band-width estimating unit 412 notifies the bandwidth estimated and the line spectrum detected to the power setting unit 413.

The power setting unit 413 derives the first power anew, on the basis of the estimated bandwidth and the estimated line spectrum that have been notified from the band-width estimating unit 412. This first power is set in the first raising unit 410. More precisely, the power setting unit 413 sets a new first power that is larger than the first power previously set, if the estimated bandwidth notified from the band-width estimating unit 412 is broader than the estimated bandwidth previously notified and if no line spectrum has been detected. On the other hand, if the estimated bandwidth notified from the band-width estimating unit 412 is as broad as or narrower than the estimated bandwidth previously notified or if a line spectrum has been detected, the first power previously set is maintained in the first raising unit 410. Note that the first power may be increased from 1 to 2, 4, 8, . . . , by a power of 2 each time, or from 1 to 2, 3, 4, . . . , by one each time. Alternatively, the first power may be increased by any other rule.

As described above, the first power is appropriately set in accordance with the bandwidth of the first raised signal 12 or with the presence or absence of a line spectrum. Hence, the present embodiment can cancel frequency offsets with a high precision, even in a system in which the symbol-modulating scheme is unknown or is adaptively changed.

### Fifth Embodiment

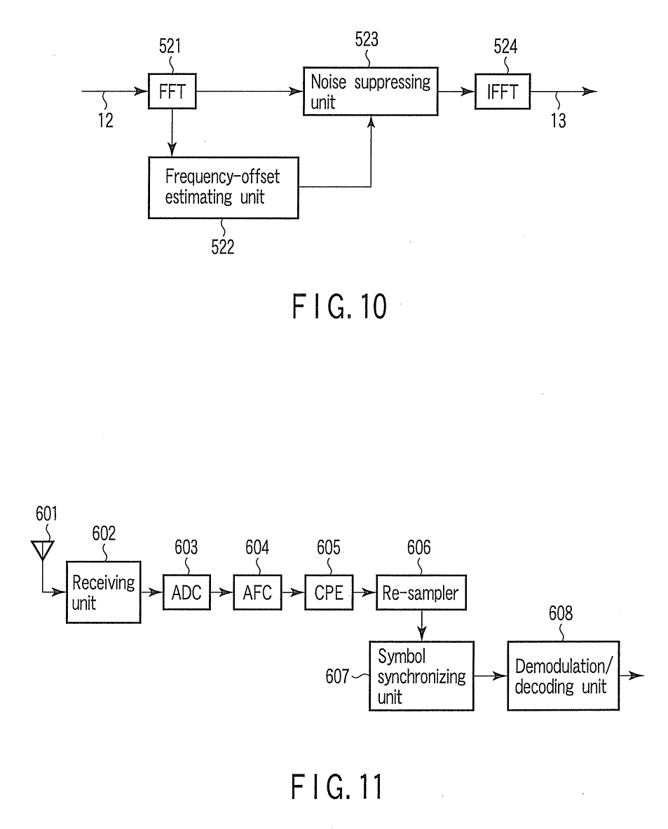

A frequency synchronizing circuit according to a fifth embodiment of this invention is different from any one of the first to fourth embodiments described above only in that the filter is replaced by a filter of the type shown in FIG. 10. As FIG. 10 shows, the filter according to the present embodiment has an FFT 521, a frequency-offset estimating unit 522, a noise suppressing unit 523, and an inverse-fast-Fourier transformer (IFFT) 524.

The FFT 521 performs FFT on the first raised signal 12, generating an amplitude spectrum. The amplitude spectrum thus generated is supplied to the frequency-offset estimating unit 522 and noise suppressing unit 523.

The frequency-offset estimating unit 522 detects, for example, conspicuous power-spectrum components whose bandwidth is narrower than a predetermined bandwidth, of a power spectrum calculated from the amplitude spectrum. From the BIN number for the maximum power-spectrum component, the frequency-offset estimating unit 522 estimates a frequency offset, which is notified to the noise suppressing unit 523.

The noise suppressing unit 523 suppresses the noise in the power-spectrum of the first raised signal 12 in accordance with the frequency offset estimated by the frequency-offset estimating unit 522. A specific method of suppressing the noise, which the noise suppressing unit 523 utilizes, will be described. The noise suppressing unit 523 may allow the passage of, for example, the first signal section for several BINs around the estimated frequency offset, and may replace the second signal section other than the first signal section, with 0. Alternatively, the noise suppressing unit 523 may multiply the power-spectrum by a window function for a bandwidth of ±several BINs with a focus on the estimated frequency offset. Still alternatively, the noise suppressing unit 523 may allow the passage of the first signal section that falls to several dBs from the level corresponding to the estimated frequency offset, and may replace the second signal section other than the first signal section with 0.

The IFFT 524 receives a signal from the noise suppressing unit 523 and performs inverse fast Fourier transform on this signal, generating a filtered signal 13. The filtered signal 13 is supplied to the second raising unit.

As described above, FFT is performed on the first raised signal 12, and the second signal section (not the first signal section near the frequency offset) is replaced by 0, in the present embodiment. The present embodiment can therefore effectively suppress noise in, for example, a single burst signal, too.

### Sixth Embodiment

As shown in FIG. 11, a receiving apparatus according, which is a sixth embodiment of this invention, has an antenna 601, a receiving unit 602, an analog-to-digital converter (ADC) 603, a frequency synchronizing circuit (AFC; Automatic Frequency Control) 604, a phase-fluctuation suppressing unit 605, a re-sampler 606, a symbol synchronizing unit 607, and a demodulation/decoding unit 608.

The antenna 601 receives a signal transmitted from a parent station (not shown) and containing a digitally modulated symbol. The receiving unit 602 down-converts the received RF signal to obtain a received signal. The ADC 603 performs analog-to-digital conversion on the received signal, converting the same to a digital signal. The digital signal is output to the frequency synchronizing circuit 604.

The frequency synchronizing circuit 604 is of the type according to any one of the first to fifth embodiments described above. The frequency synchronizing circuit 604 cancels the frequency offset from the received signal output from the ADC 603, thus generating an offset cancelled signal.

The phase-fluctuation suppressing unit 605 suppresses the moderate phase fluctuation (CPE; Common Phase Error) in the sync signal (offset cancelled signal) supplied from the frequency synchronizing circuit 604. The signal thus processed is supplied to the re-sampler 606. The re-sampler 606 reduces the fluctuation of the sampling speed pertaining to the sync signal supplied from the phase-fluctuation suppressing unit 605 by re-sampling the sync signal and supplies the sync signal to the symbol synchronizing unit 607.

The symbol synchronizing unit 607 determines the timing of extracting the symbol from the sync signal supplied from the re-sampler 606. The demodulation/decoding unit 608 can demodulate and decode the symbol at the timing determined by the symbol synchronizing unit 607.

As described above, the receiving apparatus according to this embodiment uses a frequency synchronizing circuit of the type according to any one of the first to fifth embodiments described above. Therefore, the frequency of the carrier wave used in communication between a transmitter and a receiver can also be appropriately synchronized in a system in which the unique word, not cyclic prefix, is used for guard interval sections.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A frequency synchronizing circuit comprising:
a first raising unit configured to raise a received signal by a first power to obtain a first raised signal;
a filter to suppress noise in the first raised signal to obtain a filtered signal;
a second raising unit configured to raise the filtered signal by a second power to obtain a second raised signal;
an estimating unit configured to estimate a frequency offset in the received signal based on the second raised signal to obtain an estimated value; and
an offset-cancelling unit configured to cancel the estimated value from the received signal, to output an offset cancelled signal.

2. The circuit according to claim 1, wherein the received signal contains a symbol modulated in a certain modulation scheme, and the first power has such a value that the first raising unit removes a modulated component from the received signal.

3. The circuit according to claim 1, wherein the sum of the first power and the second power is so set that an error of the estimated value may fall within a specific tolerance range.

4. The circuit according to claim 1, further comprising:
a fast Fourier transformer which performs fast Fourier transform on the first raised signal to obtain an amplitude spectrum;
a band-width estimating unit configured to estimate a bandwidth of the first raised signal based on a power spectrum acquired by squaring the amplitude spectrum; and
a setting unit configured to set the first power to a greater value if the bandwidth is broader than a threshold value.

5. The circuit according to claim 1, wherein the filter includes:
a fast Fourier transformer which performs fast Fourier transform on the first raised signal to obtain a first amplitude spectrum;
a raised-frequency-offset estimating unit configured to estimate a frequency offset of the first raised signal from a power spectrum acquired by squaring the first amplitude spectrum;
a suppressing unit configured to suppress noise in the first raised signal in accordance with the frequency offset of the first raised signal to obtain a second amplitude spectrum; and
a inverse fast Fourier transformer which performs inverse fast Fourier transform on the second amplitude spectrum to obtain the filtered signal.

6. A frequency synchronizing circuit comprising:
an offset-cancelling unit configured to cancel an cumulated estimation value of a frequency offset from an input signal, to output an offset cancelled signal;
a first raising unit configured to raise the offset cancelled signal by a first power to obtain a first raised signal;
a filter which suppresses noise in the first raised signal to obtain a filtered signal;
a second raising unit configured to raise the filtered signal by a second power to obtain a second raised signal;
an estimating unit configured to estimate the frequency offset based on the second raised signal, to obtain the cumulated estimation value and an estimated value of residual frequency offset; and
a setting unit configured to set the first power to such a value that the estimated value of residual frequency offset may fall within a specific tolerance range.

7. The circuit according to claim 6, further comprising:
a buffer which temporarily stores a received signal containing a modulated symbol or the offset cancelled signal and which outputs the stored signal as the input signal;
a switching unit configured to switch an input of the buffer such that the received signal is stored in the buffer if the estimated value of residual frequency offset has an absolute value smaller than a threshold value and the offset cancelled signal is stored in the buffer if the estimated value of residual frequency offset has an absolute value equal to or larger than the threshold value.

8. The circuit according to claim 6, wherein the input signal contains a symbol modulated in a certain modulation scheme, and the first power has such a value that the first raising unit removes a modulated component from the input signal.

9. The circuit according to claim 6, wherein the sum of the first power and the second power is so set that an error of the estimated value may fall within a specific tolerance range.

10. The circuit according to claim 6, further comprising:
a fast Fourier transformer which performs fast Fourier transform on the first raised signal to obtain an amplitude spectrum;
a band-width estimating unit configured to estimate a bandwidth of the first raised signal based on a power spectrum acquired by squaring the amplitude spectrum; and
a setting unit configured to set the first power to a greater value if the bandwidth is broader than a threshold value.

11. The circuit according to claim 6, wherein the filter includes:
a fast Fourier transformer which performs fast Fourier transform on the first raised signal to obtain a first amplitude spectrum;
a raised-frequency-offset estimating unit configured to estimate a frequency offset of the first raised signal from a power spectrum acquired by squaring the first amplitude spectrum;
a suppressing unit configured to suppress noise in the first raised signal in accordance with the frequency offset of the first raised signal to obtain a second amplitude spectrum; and
a inverse fast Fourier transformer which performs inverse fast Fourier transform on the second amplitude spectrum to obtain the filtered signal.

12. A frequency synchronizing method comprising:
rasing a received signal by a first power to obtain a first raised signal;
suppressing noise in the first raised signal to obtain a filtered signal;
raising the filtered signal by a second power to obtain a second raised signal;
estimating a frequency offset in the received signal based on the second raised signal to obtain an estimated value; and
cancelling the estimated value from the received signal, to output an offset cancelled signal.

13. A receiving apparatus comprising:
an antenna which receives a signal containing a modulated symbol to obtain a received RF signal;
a receiving unit including a down-converter which performs down-conversion on the received RF signal to obtain a received signal;
a first raising unit configured to raise the received signal by a first power to obtain a first raised signal;
a filter to suppress noise in the first raised signal to obtain a filtered signal;
a second raising unit configured to raise the filtered signal by a second power to obtain a second raised signal;
an estimating unit configured to estimate a frequency offset in the received signal based on the second raised signal to obtain an estimated value;
an offset-cancelling unit configured to cancel the estimated value from the received signal, to obtain an offset cancelled signal;
a symbol synchronizing unit configured to determine a timing of extracting the symbol from the offset cancelled signal; and
a demodulating unit configured to demodulate the symbol at the timing.

14. The apparatus according to claim 13, wherein the symbol is modulated in a certain modulation scheme, and the first power has such a value that the first raising unit removes a modulated component from the received signal.

15. The apparatus according to claim 13, wherein the sum of the first power and the second power is so set that an error of the estimated value may fall within a specific tolerance range.

16. The apparatus according to claim 13, further comprising:
a fast Fourier transformer which performs fast Fourier transform on the first raised signal to obtain an amplitude spectrum;
a band-width estimating unit configured to estimate a bandwidth of the first raised signal based on a power spectrum acquired by squaring the amplitude spectrum; and
a setting unit configured to set the first power to a greater value if the bandwidth is broader than a threshold value.

17. The apparatus according to claim 13, wherein the filter includes:
a fast Fourier transformer which performs fast Fourier transform on the first raised signal to obtain a first amplitude spectrum;
a raised-frequency-offset estimating unit configured to estimate a frequency offset of the first raised signal from a power spectrum acquired by squaring the first amplitude spectrum;
a suppressing unit configured to suppress noise in the first raised signal in accordance with the frequency offset of the first raised signal to obtain a second amplitude spectrum; and
a inverse fast Fourier transformer which performs inverse fast Fourier transform on the second amplitude spectrum to obtain the filtered signal.
